(19) United States
(12) Patent Application Publication
(10) Pub. No.: US 2017/0162826 A1
(43) Pub. Date: Jun. 8, 2017

(54) COMPOSITE BARRIER LAYER AND MANUFACTURING METHOD THEREOF

(71) Applicant: Industrial Technology Research Institute, Hsinchu (TW)

(72) Inventors: Tung-Ying Lin, Kaohsiung City (TW); Kun-Wei Lin, Tainan City (TW)

(73) Assignee: Industrial Technology Research Institute, Hsinchu (TW)

(21) Appl. No.: 15/269,945

(22) Filed: Sep. 19, 2016

(30) Foreign Application Priority Data
Dec. 7, 2015 (TW) 104140921

(51) Int. Cl. H01L 51/52; G02F 1/1333; G02F 1/167; C23C 16/515; H01J 37/32

(52) U.S. Cl. CPC H01L 51/5256; C23C 16/515; H01J 37/3244; H01J 37/32146; G02F 1/167; G02F 1/1333; H01J 2237/3321; H01J 2237/327; G02F 2001/133337

(57) ABSTRACT

A composite barrier layer including at least one first barrier layer and at least one second barrier layer disposed in a stacking manner is provided. The Si—O—Si linear bond ratio is higher than the Si—O—Si network bond ratio in the first barrier layer. The Si—O—Si network bond ratio is higher than the Si—O—Si linear bond ratio in the second barrier layer.

### CROSS-REFERENCE TO RELATED APPLICATION

This application claims the priority benefit of Taiwan application serial no. 104140921, filed on Dec. 7, 2015. The entirety of the above-mentioned patent application is hereby incorporated by reference herein and made a part of this specification.

### TECHNICAL FIELD

The disclosure relates to a barrier layer structure and a manufacturing method thereof, and more particularly, to a composite barrier layer and a manufacturing method thereof.

### BACKGROUND

The moisture-barrier capability of the electronic device is a key factor affecting the life time of the electronic device. Using an organic light-emitting diode (OLED) display as an example (such as an active matrix OLED (AMOLED) display), the substrate of a regular OLED flexible panel display is a plastic substrate (such as PET and PES), but the moisture-barrier capability and the gas-barrier capability of the plastic substrate are poor, and if a plastic substrate is used as the substrate of the OLED flexible panel display, the issue of water and oxygen permeation cannot be readily prevented. Since the polymer organic light-emitting layer and the highly-active electrode material (such as Ca and Mg) in the display and the light-emitting device are very sensitive to water and oxygen, when atmospheric water and oxygen permeate the plastic substrate, issues such as decreased brightness, increased drive voltage, dark spots, and short circuit occur. Therefore, the development of encapsulation techniques is very important to electronic device techniques.

Currently, in the encapsulation structure for an electronic device, the effects of moisture-barrier and gas-barrier is mainly achieved by using an organic and inorganic multilayer composite material formed by a vacuum sputtering method or a plasma-enhanced chemical vapor deposition method as a barrier layer. However, in the forming method of the organic and inorganic multilayer stacked structure as the barrier layer, a plurality of different chambers is required, such that the process time and the production cost of coating the barrier layer are increased.

Therefore, when forming a barrier layer having good moisture-barrier capability and gas-barrier capability, how to reduce the process time and the production cost of the battier layer is an urgent issue to be solved by those skilled in the art.

### SUMMARY

The disclosure provides a composite barrier layer including at least one first barrier layer and at least one second barrier layer disposed in a stacking manner. The Si—O—Si linear bond ratio is higher than the Si—O—Si network bond ratio in the first barrier layer. The Si—O—Si network bond ratio is higher than the Si—O—Si linear bond ratio in the second barrier layer.

According to an embodiment of the disclosure, in the composite barrier layer, the ratio of the Si—O—Si linear bond and the Si—O—Si network bond in the first barrier layer is, for instance, 1.2 to 6.

According to an embodiment of the disclosure, in the composite barrier layer, the ratio of the Si—O—Si network bond and the Si—O—Si linear bond in the second barrier layer is, for instance, 2 to 20.

According to an embodiment of the disclosure, in the composite barrier layer, the Si—O—Si bond in the component of the composite barrier layer further includes a Si—O—Si cage bond.

According to an embodiment of the disclosure, in the composite barrier layer, the ratio of the Si—O—Si bond and the Si—(CH₃)ₓ bond in the component of the composite barrier layer is, for instance, 1 to 15.

According to an embodiment of the disclosure, the composite barrier layer can be used as an encapsulation material of an electronic device, wherein the first barrier layer in the composite barrier layer is, for instance, adjacent to the electronic device.

According to an embodiment of the disclosure, the electronic device is, for instance, an organic light-emitting diode (OLED) display or an electrophoretic display (EPD).

According to an embodiment of the disclosure, the substrate of the electronic device is, for instance, a plastic substrate.

According to an embodiment of the disclosure, the material of the plastic substrate is, for instance, polyethylene terephthalate (PET), polyethersulfone (PES), polyethylene naphthalate (PEN), polyimide (PI), or polycarbonate (PC).

The disclosure provides a manufacturing method of a composite barrier layer including the following steps. An oxidizing gas and an organo-functional silane precursor are provided as process gases at a fixed ratio. The oxidizing gas and the organo-functional silane precursor form a composite barrier layer via plasma formed by a power source, and in the forming process of the composite barrier layer, the power source is set to have a plurality of different duty cycles. The composite barrier layer includes at least one first barrier layer and at least one second barrier layer disposed in a stacking manner. The Si—O—Si linear bond ratio is higher than the Si—O—Si network bond ratio in the first barrier layer. The Si—O—Si network bond ratio is higher than the Si—O—Si linear bond ratio in the second barrier layer.

According to an embodiment of the disclosure, in the manufacturing method of the composite barrier layer, the oxidizing gas is, for instance, oxygen (O₂) or nitrous oxide (N₂O).

According to an embodiment of the disclosure, in the manufacturing process of the composite barrier layer, the organo-functional silane precursor is, for instance, hexamethyldisiloxane (HMDSO), tetraethyl orthosilicate (TEOS), or tetramethylcyclotetrasiloxane (TMCTS).

According to an embodiment of the disclosure, in the manufacturing method of the composite barrier layer, the fixed ratio of the oxidizing gas and the organo-functional silane precursor is, for instance, 2 to 10.

According to an embodiment of the disclosure, in the manufacturing method of the composite barrier layer, the power source can adopt pulsed power.

According to an embodiment of the disclosure, in the manufacturing method of the composite barrier layer, the duty cycles can respectively be 1% to 99%.

According to an embodiment of the disclosure, in the manufacturing method of the composite barrier layer, the adjustment of the duty cycles can be performed at least once in a gradual increasing manner or at least once in an increasing then decreasing manner.

According to an embodiment of the disclosure, in the manufacturing method of the composite barrier layer, the ratio of the Si—O—Si linear bond and the Si—O—Si network bond in the first barrier layer is, for instance, 1.2 to 6.

According to an embodiment of the disclosure, in the manufacturing method of the composite barrier layer, the ratio of the Si—O—Si network bond and the Si—O—Si linear bond in the second barrier layer is, for instance, 2 to 20.

According to an embodiment of the disclosure, in the manufacturing method of the composite barrier layer, the Si—O—Si bond in the component of the composite barrier layer further includes a Si—O—Si cage bond.

According to an embodiment of the disclosure, in the manufacturing method of the composite barrier layer, the ratio of the Si—O—Si bond and the Si—(CH₃)ₓ bond in the component of the composite barrier layer is, for instance, 1 to 15.

Based on the above, the composite barrier layer provided by the disclosure includes at least one first barrier layer and at least one second barrier layer disposed in a stacking manner, and the Si—O—Si linear bond ratio is higher than the Si—O—Si network bond ratio in the first barrier layer and the Si—O—Si network bond ratio is higher than the Si—O—Si linear bond ratio in the second barrier layer. Accordingly, the composite barrier layer can have good moisture-barrier capability and gas-barrier capability, and therefore device reliability can be increased.

Moreover, in the manufacturing method of the composite barrier layer provided in the disclosure, the oxidizing gas and the organo-functional silane precursor are provided as process gases at a fixed ratio, and a multilayer barrier layer having different bond structure ratios is continuously formed by the oxidizing gas and the organo-functional silane precursor via plasma generated by a power source having a plurality of different duty cycles. Therefore, the manufacture of the composite barrier layer can be completed in the same chamber to achieve the objects of reduced process time and reduced production cost.

Several exemplary embodiments accompanied with figures are described in detail below to further describe the disclosure in details.

### BRIEF DESCRIPTION OF THE DRAWINGS

The accompanying drawings are included to provide a further understanding of the disclosure, and are incorporated in and constitute a part of this specification. The drawings illustrate embodiments of the disclosure and, together with the description, serve to explain the principles of the disclosure.

FIG. 1 is a manufacturing process of a composite barrier layer of an embodiment of the disclosure.

FIG. 2 is a schematic of a composite barrier layer of an embodiment of the disclosure used in electronic device encapsulation.

FIG. 3 is a cross-sectional schematic of a composite barrier layer of the first embodiment of the disclosure.

FIG. 4 is a cross-sectional schematic of a composite barrier layer of the second embodiment of the disclosure.

FIG. 5 is a cross-sectional schematic of a composite barrier layer of the third embodiment of the disclosure.

FIG. 6A to FIG. 6D are pictures of a Ca test performed on the samples of an experimental example of the disclosure.

FIG. 7A to FIG. 7C are pictures of a Ca test performed on the samples of the comparative example.

### DETAILED DESCRIPTION OF DISCLOSED EMBODIMENTS

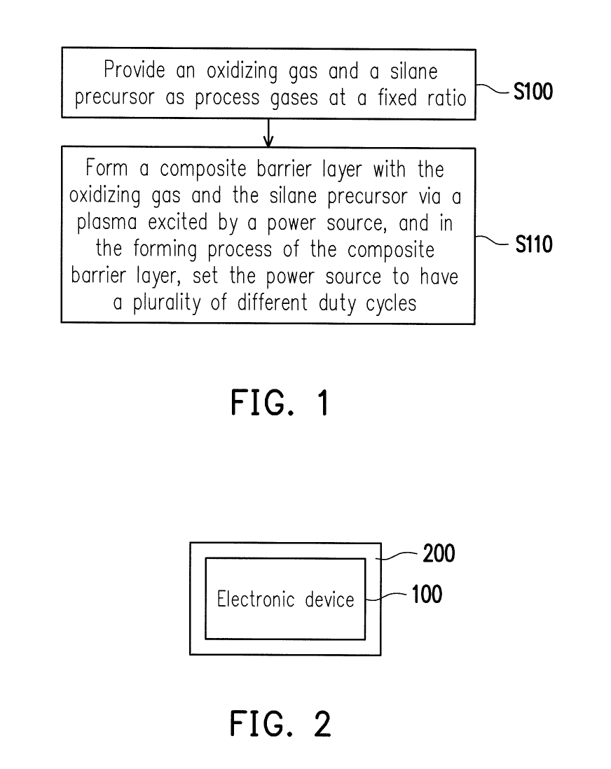

FIG. 1 is a manufacturing process of a composite barrier layer of an embodiment of the disclosure.

Referring to FIG. 1, step S100 is performed to provide an oxidizing gas and a organo-functional silane precursor as process gases at a fixed ratio. The oxidizing gas is, for instance, oxygen (O₂) or nitrous oxide (N₂O). The organo-functional silane precursor is, for instance, hexamethyldisiloxane (HMDSO), tetraethyl orthosilicate (TEOS), or tetramethylcyclotetrasiloxane (TMCTS). The fixed ratio of the oxidizing gas and the organo-functional silane precursor is, for instance, 2 to 10.

Step S110 is performed to form a composite barrier layer with the oxidizing gas and the organo-functional silane precursor via plasma excited by a power source, and in the forming process of the composite barrier layer, the power source is set to have a plurality of different duty cycles. The power source range is, for instance, 500 W to 5000 W.

The composite barrier layer can be fanned in a plasma reaction chamber of a plasma-enhanced chemical vapor deposition (PECVD) machine. The power source for generating plasma can adopt a pulsed power source to form pulsed plasma. The type of the plasma can adopt capacitively-coupled plasma (CCP) or inductively-coupled plasma (ICP). When the plasma type used is ICP, since the degree of ion bombardment of ICP is lower and ICP has lower operating temperature (such as less than 80° C.), damage to the electronic device can be prevented as the electronic device is encapsulated with the composite barrier layer. Moreover, ICP further has the advantages of simple process and reduced chemical pollution.

In the forming process of the composite barrier layer, the power source can be set to have a plurality of different duty cycles by adjusting an on time (Tₒₙ) and an off time (T_{off}). The duty cycles are defined by dividing the on time (Tₒₙ) by the total time of the on time and the off time (T_{off}) as shown in formula (1).

Duty cycle=[Tₒₙ/(Tₒₙ+T_{off})]×100% formula (1)

In the present embodiment, the duty cycles are adjusted to control the structural composition of the composite barrier layer. Therefore, by setting the power source to have a plurality of different duty cycles, the composite barrier layer can include at least one first barrier layer and at least one second barrier layer disposed in a stacking manner. The Si—O—Si linear bond ratio is higher than the Si—O—Si network bond ratio in the first barrier layer. The ratio of the Si—O—Si linear bond and the Si—O—Si network bond in the first barrier layer is, for instance, 1.2 to 6. The Si—O—network bond ratio is higher than the Si—O—Si linear bond ratio in the second barrier layer. The ratio of the Si—O—Si network bond and the Si—O—Si linear bond in the second barrier layer is, for instance, 2 to 20. The ratio of the Si—O—Si bond and the Si—(CH₃)ₓ bond in the component of the composite barrier layer is, for instance, 1 to 15. The duty cycles can respectively be 1% to 99%, and those having ordinary skill in the art can select the duty cycles of each stage according to product and process design requirements.

The Si—O—Si bond in the component of the composite barrier layer includes a Si—O—Si linear bond (as shown in general formula (a)) and a Si—O—Si network bond (as shown in general formula (b)), and can further include an intermediate Si—O—Si cage bond (as shown in general formula (c)).

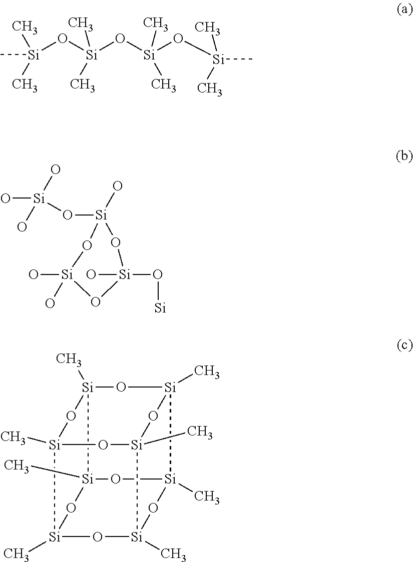

The forming mechanism of the first barrier layer and the second barrier layer in the composite barrier layer is described below. First, the forming mechanism of the first barrier layer is described. After an oxidizing gas and an organo-functional silane precursor are introduced in a reaction chamber, a power source is set to low duty cycle. At this point, the reaction time of the organo-functional silane precursor and the oxidizing gas is insufficient, the quantity of the generated Si—O—Si network bond structure is less. When the power source is turned off, the organo-functional silane precursor snore readily generates linear polymerization, and therefore more Si—O—linear bond structures are generated, such that a first barrier layer for which the Si—O—linear bond ratio is higher than the Si—O—Si network bond ratio is formed. Accordingly, the resulting first barrier layer has the function of a buffer layer, and can be used for stress relief, such that device reliability can be increased. Moreover, the first barrier layer can further have a hydrophobic effect.

Next, the forming mechanism of the second barrier layer is described. After an oxidizing gas and an organo-functional silane precursor are introduced in a reaction chamber, a power source is set to high duty cycle. At this point, the time of process gas dissociation is long, and the organo-functional silane precursor and the oxidizing gas can be sufficiently reacted, and therefore more Si—O—Si network bond structures can be generated to form a second barrier layer for which the Si—O—Si network bond ratio is higher than the Si—O—Si linear bond ratio. Accordingly, the resulting second barrier layer has better moisture-barrier capability and gas-barrier capability.

Moreover, the intermediate Si—O—Si cage bond structure between the Si—O—linear bond structure and the Si—O—Si network bond structure is a bond structure generated when oxygen atoms are not enough to replace all alkyl groups.

Furthermore, the stacking state of the first barrier layer and the second barrier layer can be configured by the adjustment method of the duty cycles to decide the characteristics of the composite barrier layer to be formed. For instance, the adjustment of the duty cycles can be performed at least once in a gradual increasing manner or at least once in an increasing then decreasing manner. Moreover, the relation of the adjustment method of the duty cycles and the structural composition of the composite barrier layer is described in the embodiments below.

It can be known from the above embodiments that, in the manufacturing method of the composite barrier layer, the oxidizing gas and the organo-functional silane precursor are provided as process gases at a fixed ratio, and a multilayer barrier layer having different bond structure ratios is continuously formed by the oxidizing gas and the organo-functional silane precursor via plasma generated by a power source having a plurality of different duty cycles. Therefore, the manufacture of the composite barrier layer can be completed in the same chamber to achieve the objects of reduced process time and reduced production cost.

In the following, the application of the composite barrier layer and the structural configuration of the composite barrier layer of an embodiment of the disclosure are described with examples, but the disclosure is not limited thereto.

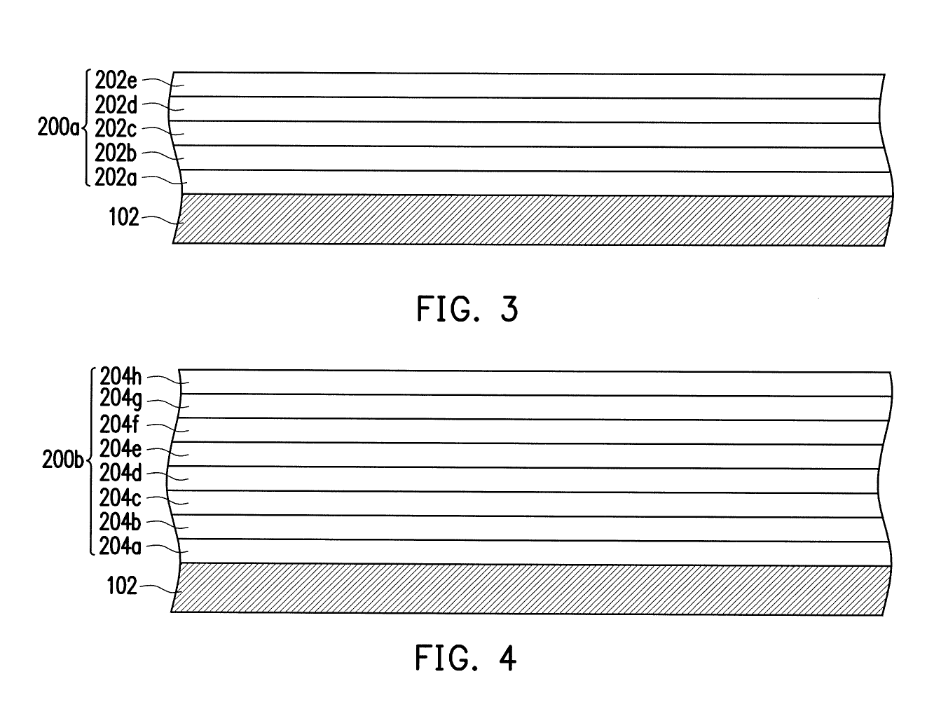

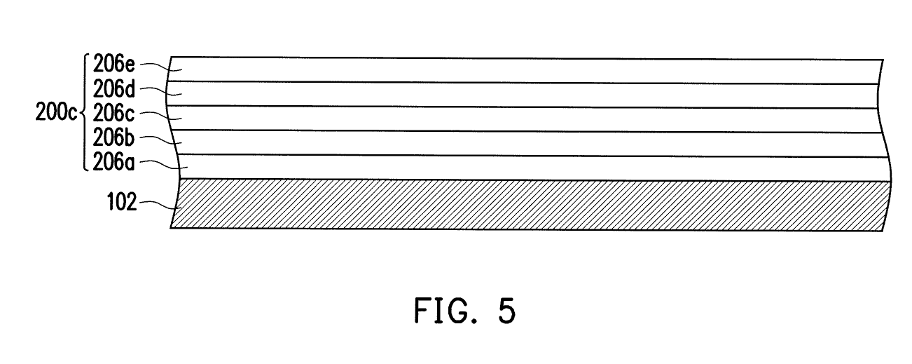

FIG. 2 is a schematic of a composite barrier layer of an embodiment of the disclosure used in electronic device encapsulation. FIG. 3 is a cross-sectional schematic of a composite barrier layer of the first embodiment of the disclosure. FIG. 4 is a cross-sectional schematic of a composite barrier layer of the second embodiment of the disclosure. FIG. 5 is a cross-sectional schematic of a composite barrier layer of the third embodiment of the disclosure.

Referring to FIG. 2, FIG. 2 describes the application of using a composite barrier layer 200 of the present embodiment as the encapsulation material of an electronic device 100, but the disclosure is not limited thereto. Those having ordinary skill in the art can also apply the composite barrier layer of the present embodiment in other moisture-barrier and gas-barrier applications. The electronic device 100 is, for instance, an OLED display (such as an active matrix OLED (AMOLED) display) or an electrophoretic display. Referring to FIG. 2 to FIG. 5, the electronic device 100 has a substrate 102. The substrate 102 is, for instance, a plastic substrate, and the material of the plastic substrate is, for instance, PET, PES, PEN, PI, or PC.

The structural configuration of the composite barrier layer 200 can be decided by the adjustment method of the duty cycles of the power source. For instance, the composite barrier layer 200 can be a composite barrier layer 200a of FIG. 3, a composite barrier layer 200b of FIG. 4, or a composite barrier layer 200c of FIG. 5.

Referring to FIG. 3, when the composite barrier layer 200a is formed, the electronic device 100 can be first placed in the plasma reaction chamber of a PECVD machine, and then the composite barrier layer 200a is formed on the substrate 102 via the manufacturing method of the composite barrier layer provided in the embodiment of FIG. 1. In particular, the adjustment of the duty cycles can be performed at least once in a gradual increasing manner. In the present embodiment, the adjustment method of the duty cycles is exemplified by adjusting once in a gradual increasing manner, but the disclosure is not limited thereto. In other embodiments, the adjustment of the duty cycles can also be performed twice or more in a gradual increasing manner. The duty cycles can be 1% to 99%.

In the forming process of the composite barrier layer 200a, by setting the power source to have five gradual increasing duty cycles, the resulting composite barrier layer 200a can include barrier layers 202a to 202e disposed in a stacking manner, and the barrier layers 202a to 202e have different bond structure ratios. For instance, the power source can be set to have 20%, 40%, 60%, 80% and 99% duty cycles, but the disclosure is not limited thereto.

Since the duty cycles for foiiiiing the barrier layers 202a to 202e are gradually increasing, the Si—O—Si network bond in the barrier layers 202a to 202e is increasing and the Si—O—Si linear bond is decreasing.

The barrier layer 202a in the composite barrier layer 200a is adjacent to the substrate 102 of the electronic device 100. Since the barrier layer 202a is formed at the lowest duty cycle, the Si—O—Si linear bond ratio of the barrier layer 202a is higher than the Si—O—Si network bond ratio, and the function of a buffer layer is achieved, such that the stress of the barrier layers 202b to 202e subsequently formed thereon can be released, and device reliability can be increased as a result. The ratio of the Si—O—Si linear bond and the Si—O—Si network bond in the barrier layer 202a is, for instance, 1.2 to 6.

Moreover, since the barrier layer 202e is formed at a higher duty cycle, the Si—O—network bond ratio is higher than the Si—O—Si linear bond ratio in the barrier layer 202e, and better moisture-barrier capability and gas-barrier capability are achieved. The ratio of the Si—O—Si network bond and the Si—O—Si linear bond in the barrier layer 202e is, for instance, 2 to 20.

Moreover, the ratio of the Si—O—Si bond and the Si—(CH₃)ₓ bond in the component of the composite barrier layer 200a is, for instance, 1 to 15. In the forming process of the composite barrier layer 200a, if the supply of the oxygen atoms is insufficient, then the Si—O—Si bond in the component of the barrier layers 202a to 202e of the composite barrier layer 200a may also include a Si—O—Si cage bond.

Although the above embodiments are exemplified by setting the power source to have five gradual increasing duty cycles to form five barrier layers (i.e., the barrier layers 202a to 202e), the disclosure is not limited thereto. Those having ordinary skill in the art can adjust the duty cycles and the quantity of the barrier layer according to product requirements.

It can be known from the above embodiments that, since the composite barrier layer 200a includes at least one barrier layer (such as the barrier layer 202a) for which the Si—O—Si linear bond ratio is higher than the Si—O—Si network bond ratio and at least one barrier layer (such as the barrier layer 202e) for which the Si—O—Si network bond ratio is higher than the Si—O—Si linear bond ratio, the composite barrier layer 200a can have good moisture-barrier capability and gas-barrier capability, and therefore device reliability can be increased.

Referring to both FIG. 3 and FIG. 4, the difference between the first embodiment of FIG. 3 and the second embodiment of FIG. 4 is as follows. The adjustment of the duty cycle of the second embodiment of FIG. 4 is performed twice in a gradual increasing manner to form the composite barrier layer 200b on the substrate 102. The composite barrier layer 200b includes barrier layers 204a to 204h disposed in a stacking manner.

Since the duty cycles for forming the barrier layers 204a to 204d are gradually increasing, the Si—O—Si network bond is gradually increasing and the Si—O—Si linear bond is gradually decreasing in the barrier layers 204a to 204d. Moreover, since the duty cycles for forming the barrier layers 204e to 204h are gradually increasing, the Si—O—network bond is gradually increasing and the Si—O—Si linear bond is gradually decreasing in the barrier layers 204e to 204h. In particular, the Si—O—Si linear bond ratio is higher than the Si—O—Si network bond ratio in the barrier layers 204a and 204e, such that the function of a buffer layer is achieved. The Si—O—Si network bond ratio is higher than the Si—O—Si linear bond ratio in the barrier layers 204d and 204h, such that better moisture-barrier capability and gas-barrier capability are achieved.

It can be known from the above embodiments that, since the composite barrier layer 200b includes at least two barrier layers (such as the barrier layers 204a and 204e) for which the Si—O—Si linear bond ratio is higher than the Si—O—Si network bond ratio and at least two barrier layers (such as the barrier layers 204d and 204h) for which the Si—O—network bond ratio is higher than the Si—O—Si linear bond ratio, the composite barrier layer 200b can have better moisture-barrier capability and gas-barrier capability, and therefore device reliability can be further increased.

Referring to both FIG. 3 and FIG. 5, the difference between the first embodiment of FIG. 3 and the third embodiment of FIG. 5 is as follows. The adjustment of the duty cycles of the third embodiment of FIG. 5 is performed once in a gradual increasing then gradual decreasing manner to form the composite barrier layer 200c on the substrate 102. The composite barrier layer 200c includes barrier layers 206a to 206e disposed in a stacking manner.

Since the duty cycles for forming the barrier layers 206a to 206c are gradually increasing, the Si—O—Si network bond is gradually increasing and the Si—O—Si linear bond is gradually decreasing in the barrier layers 206a to 206c. Moreover, since the duty cycles for forming the barrier layers 206d and 206e are gradually decreasing, the Si—O—network bond is gradually decreasing and the Si—O—Si linear bond is gradually increasing in the barrier layers 206d and 206e. In particular, the Si—O—Si linear bond ratio is higher than the Si—O—Si network bond ratio in the barrier layers 206a, such that the function of a buffer layer is achieved. Moreover, the Si—O—Si linear bond ratio is higher than the Si—O—Si network bond ratio in the outermost barrier layer 206e, such that hydrophobic characteristic is achieved. The Si—O—Si network bond ratio is higher than the Si—O—Si linear bond ratio in the barrier layer 206c, such that better moisture-barrier capability and gas-barrier capability are achieved.

It can be known from the above embodiments that, since the composite barrier layer 200c includes at least two barrier layers (such as the barrier layers 206a and 206e) for which the Si—O—Si linear bond ratio is higher than the Si—O—network bond ratio and at least one barrier layer (such as the barrier layer 206c) for which the Si—O—network bond ratio is higher than the Si—O—Si linear bond ratio, the composite barrier layer 200c can have good moisture-barrier capability and gas-barrier capability, and the composite barrier layer 200c can have hydrophobic characteristic on the outer surface, and device reliability can be increased at the same time.

Although the composite barrier layers 200a to 200c in the above embodiments are described via the layer numbers shown in FIG. 3 to FIG. 5, the disclosure is not limited thereto. Any composite barrier layer having at least one barrier layer for which the Si—O—linear bond ratio is higher than the Si—O—network bond ratio and at least one barrier layer for which the Si—O—network bond ratio is higher than the Si—O—linear bond ratio is within the scope of the disclosure.

Experiment A: Thin Film Analysis Experiment

After bond analysis for thin films formed by different duty cycles was performed using a Fourier transform infrared (FTIR) spectroscope, the following results were obtained. A higher duty cycle made the peak shift toward the wavenumber 1072 cm⁻¹, indicating the component of the barrier layer had more Si—O—network bond structures and water vapor could be better blocked. A lower duty cycle made the peak position closer to the wavenumber 1023 cm⁻¹, indicating the component of the barrier layer had more linear bond structures and the function of a buffer layer was achieved. Moreover, a greater quantity of the cage bond structure in the component of the barrier layer made the peak position closer to the wavenumber 1132 cm⁻¹.

Experiment B: Water Vapor Transmittance Experiment (MOCON Water Vapor Transmittance Measuring Instrument)

The composite barrier layers of experimental example B-1 to experimental example B-8 were formed by the manufacturing method of the barrier layer provided in the embodiment of FIG. 1. In particular, the fixed ratio of N₂O and HMDSO was set to 5. In experimental example B-1 to experimental example B-7, the flow rate of N₂O was 250 sccm and the flow rate of HMDSO was 50 sccm. In experimental example B-8, the flow rate of N₂O was 400 sccm and the flow rate of HMDSO was 80 sccm. The environmental conditions were 40° C. and 90% RH. The thickness of each of the composite barrier layers in experimental example B-1 to experimental example B-6 was 120 nm. The thickness of the composite barrier layer in experimental example B-7 was 150 nm. The thickness of the composite barrier layer in experimental example B-8 was 400 nm.

A measurement of water vapor transmittance rate (WVTR) was performed on the composite barrier layers of experimental example B-1 to experimental example B-8 using a MOCON water vapor transmittance measuring instrument (model: AQUATRAN). Other parameter settings in experimental example B and the experimental results are shown in Table 1.

TABLE 1

| Experi- | | | Duty | | | |
|---|---|---|---|---|---|---|
| mental | | | cycle | | | |
| Exam- | Adjustment | Power | of each | Tₒₙ | T_{off} | WVTR |
| ple No. | of duty cycle | (W) | stage | (msec) | (msec) | (g/m²/day) |
| B-1 | Performed | 800 | 10% | 0.1 | 0.9 | 0.026 |
| | once in | | 30% | 0.3 | 0.7 | |
| | gradual | | 50% | 0.5 | 0.5 | |
| | increasing | | 70% | 0.7 | 0.3 | |
| | manner | | 99% | 0.99 | 0.01 | |
| B-2 | | 800 | 25% | 0.25 | 0.75 | 0.030 |
| | | | 40% | 0.4 | 0.6 | |
| | | | 55% | 0.55 | 0.45 | |
| | | | 70% | 0.7 | 0.3 | |
| | | | 99% | 0.99 | 0.01 | |
| B-3 | | 800 | 50% | 0.5 | 0.5 | 0.040 |
| | | | 60% | 0.6 | 0.4 | |
| | | | 70% | 0.7 | 0.3 | |
| | | | 80% | 0.8 | 0.2 | |
| | | | 99% | 0.99 | 0.01 | |
| B-4 | | 1600 | 10% | 0.1 | 0.9 | 0.008 |
| | | | 30% | 0.3 | 0.7 | |
| | | | 50% | 0.5 | 0.5 | |
| | | | 70% | 0.7 | 0.3 | |
| | | | 99% | 0.99 | 0.01 | |
| B-5 | | 1600 | 25% | 0.25 | 0.75 | 0.011 |
| | | | 40% | 0.4 | 0.6 | |
| | | | 55% | 0.55 | 0.45 | |
| | | | 70% | 0.7 | 0.3 | |
| | | | 99% | 0.99 | 0.01 | |
| B-6 | | 1600 | 50% | 0.5 | 0.5 | 0.017 |
| | | | 60% | 0.6 | 0.4 | |
| | | | 70% | 0.7 | 0.3 | |
| | | | 80% | 0.8 | 0.2 | |
| | | | 99% | 0.99 | 0.01 | |
| B-7 | Performed | 1600 | 10% | 0.1 | 0.9 | 0.007 |
| | once in | | 50% | 0.5 | 0.5 | |
| | gradual | | 70% | 0.7 | 0.3 | |
| | increasing | | 90% | 0.9 | 0.1 | |
| | then gradual | | 30% | 0.3 | 0.7 | |
| | decreasing | | | | | |
| | manner | | | | | |
| B-8 | Performed | 2000 | 10% | 0.1 | 0.9 | less than |
| | twice in | | 20% | 0.2 | 0.8 | 5 × 10⁻⁴ |
| | gradual | | 30% | 0.3 | 0.7 | |
| | increasing | | 40% | 0.4 | 0.6 | |
| | manner | | 50% | 0.5 | 0.5 | |
| | | | 60% | 0.6 | 0.4 | |
| | | | 70% | 0.7 | 0.3 | |
| | | | 80% | 0.8 | 0.2 | |
| | | | 90% | 0.9 | 0.1 | |
| | | | 20% | 0.2 | 0.8 | |
| | | | 40% | 0.4 | 0.6 | |
| | | | 60% | 0.6 | 0.4 | |
| | | | 80% | 0.8 | 0.2 | |
| | | | 99% | 0.99 | 0.01 | |

It can be known from the test results that, the composite barrier layers of experimental example B-1 to experimental example B-8 all have good moisture-barrier capability. Moreover, since WVTR (water vapor transmittance rate) and OTR (oxygen transmittance rate) have a positive correlation, it can be known from the test results that, the composite barrier layers of experimental example B-1 to experimental example B-8 also have good gas-barrier capability.

Experiment C: Water Vapor Transmittance Experiment (Ca Test)

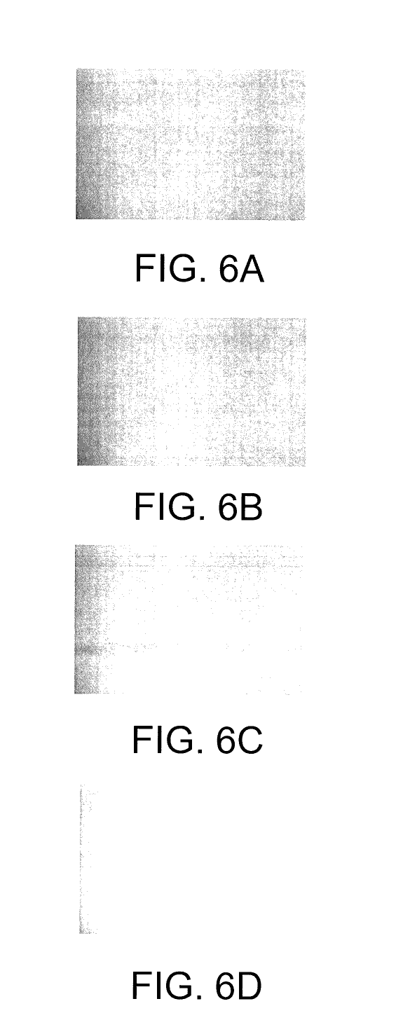

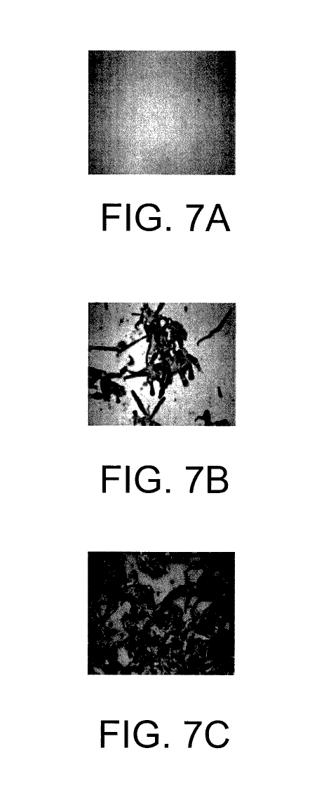

FIG. 6A to FIG. 6D are pictures of a Ca test performed on the samples of an experimental example of the disclosure. FIG. 7A to FIG. 7C are pictures of a Ca test performed on the samples of the comparative example.

The Ca test can be used to measure the range (less than 5×10⁻⁴ g/m²/day) that cannot be measured by a MOCON water vapor transmittance measuring instrument. Therefore, the water vapor transmittance rate of the composite barrier layer of experimental example B-8 was measured via a Ca test.

In the present experimental example, the method of measuring the water vapor transmittance rate via a Ca test is as follows. First, the samples of experimental example B-8 were prepared. The composite barrier layer of experimental example B-8, a calcium film, and a copper film were formed on a PEN flexible substrate in order, and then the PEN flexible substrate and a glass substrate were laminated and sealing was performed via a photosensitive UV epoxy resin to seal the calcium film and the copper film between the PEN flexible substrate and the glass substrate. Then, the test samples were placed in an environment of 40° C. and 100% RH, and the water vapor transmittance rate was obtained by conversing the oxidation rate of calcium. The manufacturing method of the samples of the comparative example was the same as that of the samples of experimental example B-8, and the difference is that the samples of the comparative example did not include the composite barrier layer.

Since metal calcium has a metallic luster, the calcium film was rapidly oxidized and became colorlessly transparent. Therefore, in the water vapor transmittance experiment of the Ca test, after water vapor passed through the PEN flexible substrate, if the water moisture-barrier capability of the composite barrier layer of experimental example B-8 was poor, then the calcium film was in contact with the water vapor and became colorlessly transparent, and the color of the copper substrate therebelow (hereinafter “copper color”) was shown.

The experimental results are shown below. Referring to FIG. 6A to FIG. 6D, copper color was not observed in the samples of experimental example B-8 after day 0 (FIG. 6A), day 10 (FIG. 6B), day 15 (FIG. 6C), and day 25 (FIG. 6D), and therefore it can be known that the composite barrier layer of experimental example B-8 has relatively better moisture-barrier capability. Moreover, referring to FIG. 7A to FIG. 7C, since the samples of the comparative example did not include the composite barrier layer, except that no significant copper color was observed on day 0 (FIG. 7A), significant copper color was already observed on day 1 (FIG. 7B), and lots of copper color was observed on day 3 (FIG. 7C).

The oxidation percentage of each of the samples of experimental example B-8 is as shown in Table 2, and the water vapor transmittance rate obtained from conversion is 1×10⁻⁶ g/m²/day. Before coating, the water vapor transmittance rate of a regular plastic substrate (such as PEN) was 1.6 g/m²/day, and after the composite barrier layer of experimental example B-8 was coated, the water vapor transmittance rate could be reduced to 1×10⁻⁶ g/m²/day, indicating the composite barrier layer of experimental example B-8 had relatively better moisture-barrier capability.

TABLE 2

| Number of days | Day 0 | Day 10 | Day 15 | Day 25 |
|---|---|---|---|---|
| Oxidation percentage | 0% | 0% | 0% | 0% |

Based on the above, the composite barrier layer of the embodiments includes at least one barrier layer for which the Si—O—Si linear bond ratio is higher than the Si—O—Si network bond ratio and at least one barrier layer for which the Si—O—Si network bond ratio is higher than the Si—O—Si linear bond ratio, and therefore the composite balder layer can have good moisture-barrier capability and gas-barrier capability, and device reliability can be increased as a result.

Moreover, in the manufacturing method of the composite barrier layer of the embodiments, the oxidizing gas and the organo-functional silane precursor are provided as process gases at a fixed ratio, and a multilayer barrier layer having different bond structure ratios is continuously formed by the oxidizing gas and the organo-functional silane precursor via plasma generated by a power source having a plurality of different duty cycles. Therefore, the manufacture of the composite barrier layer can be completed in the same chamber to achieve the objects of reduced process time and reduced production cost.

It will be apparent to those skilled in the art that various modifications and variations can be made to the structure of the disclosed embodiments without departing from the scope or spirit of the disclosure. In view of the foregoing, it is intended that the disclosure cover modifications and variations of this disclosure provided they fall within the scope of the following claims and their equivalents.

What is claimed is:

1. A composite barrier layer, comprising at least one first barrier layer and at least one second barrier layer disposed in a stacking manner, wherein
a Si—O—Si linear bond ratio is higher than a Si—O—Si network bond ratio in the at least one first barrier layer,
a Si—O—Si network bond ratio is higher than a Si—O—Si linear bond ratio in the at least one second barrier layer.

2. The composite barrier layer of claim 1, wherein a ratio of a Si—O—Si linear bond and a Si—O—Si network bond in the at least one first barrier layer is 1.2 to 6.

3. The composite barrier layer of claim 1, wherein a ratio of a Si—O—network bond and a Si—O—Si linear bond in the at least one second barrier layer is 2 to 20.

4. The composite barrier layer of claim 1, wherein a Si—O—Si bond in a component of the composite barrier layer further comprises a Si—O—Si cage bond.

5. The composite barrier layer of claim 1, wherein a ratio of a Si—O—Si bond and a Si—(CH₃)ₓ bond in a component of the composite barrier layer is 1 to 15.

6. The composite barrier layer of claim 1, wherein the composite barrier layer is used as an encapsulation material for an electronic device, and the first barrier layer in the composite barrier layer is adjacent to the electronic device.

7. The composite barrier layer of claim 6, wherein the electronic device comprises an organic light-emitting diode display or an electrophoretic display.

8. The composite barrier layer of claim 6, wherein a substrate of the electronic device comprises a plastic substrate.

9. The composite barrier layer of claim 8, wherein a material of the plastic substrate comprises polyethylene terephthalate, polyethersulfone, polyethylene naphthalate, polyimide, or polycarbonate.

10. A manufacturing method of a composite barrier layer, comprising:
providing an oxidizing gas and a organo-functional silane precursor as process gases at a fixed ratio; and
forming a composite barrier layer with the oxidizing gas and the organo-functional silane precursor via a plasma excited by a power source, wherein in the forming process of the composite barrier layer, the power source is set to have a plurality of different duty cycles, the composite barrier layer comprises at least one first barrier layer and at least one second barrier layer disposed in a stacking manner,
a Si—O—linear bond ratio is higher than a Si—O—network bond ratio in the at least one first barrier layer, and
a Si—O—network bond ratio is higher than a Si—O—linear bond ratio in the at least one second barrier layer.

11. The manufacturing method of the composite barrier layer of claim 10, wherein the oxidizing gas comprises oxygen (O₂) or nitrous oxide (N₂O).

12. The manufacturing method of the composite barrier layer of claim 10, wherein the organo-functional silane precursor comprises hexamethyl disiloxane, tetraethyl orthosilicate, or tetramethylcyclotetrasiloxane.

13. The manufacturing method of the composite barrier layer of claim 10, wherein the fixed ratio of the oxidizing gas and the organo-functional silane precursor is 2 to 10.

14. The manufacturing method of the composite barrier layer of claim 10, wherein the power source comprises a pulsed power source.

15. The manufacturing method of the composite barrier layer of claim 10, wherein the duty cycles are respectively 1% to 99%.

16. The manufacturing method of the composite barrier layer of claim 10, wherein an adjustment of the duty cycles is performed at least once in a gradual increasing manner or at least once in an increasing then decreasing manner.

17. The manufacturing method of the composite barrier layer of claim 10, wherein a ratio of a Si—O—Si linear bond and a Si—O—Si network bond in the at least one first barrier layer is 1.2 to 6.

18. The manufacturing method of the composite barrier layer of claim 10, wherein a ratio of a Si—O—Si network bond and a Si—O—Si linear bond in the at least one second barrier layer is 2 to 20.

19. The manufacturing method of the composite barrier layer of claim 10, wherein a Si—O—Si bond in a component of the composite barrier layer further comprises a Si—O—Si cage bond.

20. The manufacturing method of the composite barrier layer of claim 10, wherein a ratio of a Si—O—Si bond and a Si—(CH₃)ₓ bond in a component of the composite barrier layer is 1 to 15.
